(19) United States
(12) Patent Application Publication
(10) Pub. No.: US 2012/0009724 A1
(43) Pub. Date: Jan. 12, 2012

(54) METHOD FOR HANDLING A FLEXIBLE SUBSTRATE OF SOLAR CELL

(76) Inventor: Seung-Yeop Myong, Seoul (KR)

(21) Appl. No.: 13/176,546

(22) Filed: Jul. 5, 2011

(30) Foreign Application Priority Data
Jul. 8, 2010 (KR) 10-2010-0065987

(51) Int. Cl. H01L 31/18

(52) U.S. Cl. 438/73; 257/E31.001

(57) ABSTRACT

Disclosed is a method for handling a flexible substrate of solar cell. The method includes: providing a flexible substrate; performing static electricity removal and atmospheric pressure plasma cleaning with respect to the flexible substrate; forming a first electrode on the flexible substrate; forming a first conductive semiconductor layer, an intrinsic semiconductor layer and a second conductive semiconductor layer on the first electrode; and forming a second electrode on the second conductive semiconductor layer.

### CROSS-REFERENCE TO RELATED APPLICATIONS

This application claims priority under 35 U.S.C. §119 to Korean Patent Application No. 10-2010-0065987 filed on Jul. 8, 2010, the entirety of which is hereby incorporated by reference.

### FIELD OF THE INVENTION

The present invention relates to a method for cleaning a flexible substrate of a solar cell.

### BACKGROUND OF THE INVENTION

Recently, as existing energy resources like oil and coal and the like are expected to be exhausted, much attention is increasingly paid to alternative energy sources which can be used in place of the existing energy sources. As an alternative energy source, sunlight energy is abundant and has no environmental pollution. Therefore, more and more attention is paid to the sunlight energy.

A photovoltaic device, that is, a solar cell directly converts sunlight energy into electrical energy. The photovoltaic device mainly uses photovoltaic effect of semiconductor junction. In other words, when light is incident on and absorbed by a semiconductor p-n junction doped with p-type impurity and n-type impurity respectively, light energy generates electrons and holes within the semiconductor and the electrons and the holes are separated from each other by an internal electric field. As a result, a photo-electro motive force is generated between both ends of the p-n junction. Here, when electrodes are formed at both ends of the junction and connected with wires, electric current flows externally through the electrodes and the wires.

In order that the existing energy sources such as oil is substituted with the sunlight energy source, it is necessary to provide a solar cell with high photovoltaic conversion efficiency.

### SUMMARY OF THE INVENTION

One aspect of the present invention is a method for handling a flexible substrate of solar cell. The method includes: providing a flexible substrate; performing static electricity removal and atmospheric pressure plasma cleaning with respect to the flexible substrate; forming a first electrode on the flexible substrate; forming a first conductive semiconductor layer, an intrinsic semiconductor layer and a second conductive semiconductor layer on the first electrode; and forming a second electrode on the second conductive semiconductor layer.

Another aspect of the present invention is a solar cell manufacturing system including a flexible substrate. The solar cell manufacturing system includes: a roll on which the flexible substrate can be wound; at least one process chamber for forming a first conductive semiconductor layer, an intrinsic semiconductor layer and a second conductive semiconductor layer; a transfer device passes the flexible substrate through the at least one process chamber as the roll rotates; and a static electricity remover for removing static electricity of the flexible substrate placed between the roll and the at least one chamber.

The manufacturing system may further comprises an atmospheric pressure plasma cleaner for cleaning the flexible substrate between the roll and the at least one chamber.

### BRIEF DESCRIPTION OF THE DRAWINGS

FIGS. 1a and 1b show a manufacturing system for a solar cell including a flexible substrate.

FIG. 2 shows a static electricity remover which can be used to remove static electricity of the flexible substrate in accordance with the embodiment of the present invention.

FIG. 3 shows an atmospheric pressure plasma cleaner which can be used to clean the flexible substrate in accordance with the embodiment of the present invention.

### DETAILED DESCRIPTION

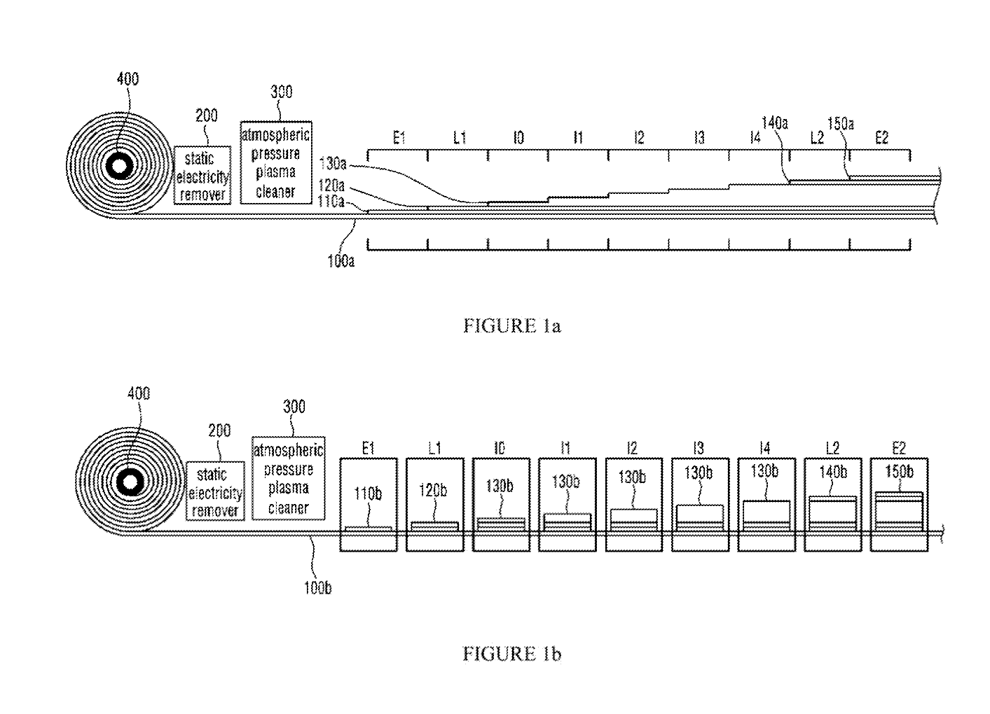

An embodiment of the present invention will be described in detail with reference to the drawings. FIGS. 1a and 1b show a manufacturing system for a solar cell including a flexible substrate.

FIG. 1a shows a roll-to-roll type solar cell manufacturing system. FIG. 1b shows a stepping roll type solar cell manufacturing system.

As shown in FIGS. 1a and 1b, each system includes a plurality of process chambers I0 to I4 for forming an intrinsic semiconductor layer. Intrinsic semiconductor layers 130a and 130b of a solar cell are thicker than first conductive semiconductor layers 120a and 120b or second conductive semiconductor layers 140a and 140b. Therefore, the solar cell manufacturing system may include a larger number of the process chambers than the process chambers L1 and L2 that are used to form the first conductive semiconductor layers 120a and 120b and the second conductive semiconductor layers 140a and 140b, respectively. The first conductive semiconductor layers 120a and 120b, the second conductive semiconductor layers 140a and 140b, or the intrinsic semiconductor layers 130a and 130b can be formed in a process chamber in which a PECVD (Plasma Enhanced Chemical Vapor Deposition) process is performed.

Here, when the first conductive semiconductor layers 120a and 120b are p-type semiconductor layers, the second conductive semiconductor layers 140a and 140b are n-type semiconductor layers. Also, when the first conductive semiconductor layers 120a and 120b are n-type semiconductor layers, the second conductive semiconductor layers 140a and 140b are p-type semiconductor layers.

The roll-to-roll type solar cell manufacturing system or the stepping roll type solar cell manufacturing system can be used to manufacture a solar cell including a flexible substrate 100a and 100b such as a metal foil or a polymer substrate. In the process chambers L1, I0 to I4 and L2, the first conductive semiconductor layer 120a and 120b, the intrinsic semiconductor layer 130a and 130b and the second conductive semiconductor layer 140a and 140b can be formed on the flexible substrate 100a and 100b.

For example, when hydrogen gas, silicon-containing gas like silane gas, and group III doping gas like B₂H₆ are introduced into the process chamber L1, a p-type semiconductor layer is formed on the flexible substrate 100a and 100b. Further, when hydrogen gas, silicon-containing gas, and group V doping gas like PH₃ are introduced into the process chamber L1, an n-type semiconductor layer is formed on the flexible substrate 100a and 100b. Hydrogen gas and silicon-containing gas are introduced into the process chamber groups I0 to I4 for forming the intrinsic semiconductor layer 130a and 130b. When a p-type semiconductor layer is formed in the process chamber L1, an n-type semiconductor layer is formed in the process chamber L2. When an n-type semiconductor layer is formed in the process chamber L1, a p-type semiconductor layer is formed in the process chamber L2.

In the roll-to-roll type manufacturing system of FIG. 1a, while a roll 400 continuously rotates, the flexible substrate 100a rolled in the roll 400 passes through the insides of the process chambers. As a result, a first electrode 110a, a first conductive semiconductor layer 120a, an intrinsic semiconductor layer 130a, a second conductive semiconductor layer 140a and a second electrode 150a are continuously formed on the flexible substrate 100a.

In the stepping roll type manufacturing system of FIG. 1b, the roll 400 rotates and stops repetitively. During the rotation of the roll 400, a gate (not shown) or a top plate (not shown) of each of the process chambers is opened and the flexible substrate 100b moves. During the stop of the roll 400, the gate or the top plate is closed and the then a first electrode 110b, a first conductive semiconductor layer 120b, an intrinsic semiconductor layer 130b, a second conductive semiconductor layer 140b and a second electrode 150b are continuously formed on the flexible substrate 100b in each process chamber.

As shown in FIGS. 1a and 1b, whenever the flexible substrates 100a and 100b pass by the process chambers I0 to I4, the intrinsic semiconductor layers 130a and 130b become thicker.

The manufacturing systems described above include process chambers E1 and E2 which are used to form the first electrode 110a and 110b and the second electrode 150a and 150b respectively. However, the manufacturing systems described above may not include the process chambers E1 and E2 used to form the electrodes. The first electrode 110a and 110b and the second electrode 150a and 150b are formed in the process chambers E1 and E2 by performing a sputtering process.

The first electrode 110a and 110b and the second electrode 150a and 150b are placed on the flexible substrate 100a and 100b. The first conductive semiconductor layer 120a and 120b, the intrinsic semiconductor layer 130a and 130b and the second conductive semiconductor layer 140a and 140b are placed between the first electrode 110a and 110b and the second electrode 150a and 150b.

The manufacturing systems shown in FIGS. 1a and 1b can produce a single junction solar cell including the first conductive semiconductor layer 120a and 120b, the intrinsic semiconductor layer 130a and 130b and the second conductive semiconductor layer 140a and 140b, and can also produce a tandem type solar cell by further including separate process chambers that can be used to form another first conductive semiconductor layer, intrinsic semiconductor layer and second conductive semiconductor layer.

Meanwhile, an integration process, such as a laser scribing process, connecting adjacent cells in series may be performed between the process chambers, or may be performed after the second electrode is formed. Further, the integration process may be performed after the first electrode is formed, or may be performed within a period from a time after the second conductive semiconductor layer is formed to a time before the second electrode is formed. The integration process may be also performed between the roll-to-roll type manufacturing systems as well.

When a laser scribing process is performed on any one of the first electrode 110a and 110b and the second electrode 150a and 150b, there may remain conductive particles on the flexible substrate 100a and 100b. In the embodiment of the present invention, a cleaning process may be performed, in which an ultra sonic cleaner including a suction head removes the conductive particles.

The ultra sonic cleaner purifies cooling dried air by passing the cooling dried air through a hepa filter, and then blows the cooling dried air to the flexible substrate 100a and 100b at a regular cycle by a blow unit. An ultrasonic wave is hereby generated and then the conductive particles on the flexible substrate 100a and 100b are floated. Then, the suction head sucks the floated particles and a pre-filter of the ultra sonic cleaner collects the particles.

As such, in the embodiment of the present invention, the conductive particles are removed by using the ultrasonic cleaning instead of wet cleaning. As regards the wet cleaning, it costs a lot for cleaning and it may have a bad influence on the performance of the solar cell due to immersion of the substrate into a solution. Meanwhile, since the ultra sonic cleaning is performed at an atmospheric pressure without using a solution, it is possible to reduce the cost and a bad influence on the performance of the solar cell.

In the embodiment of the present invention, when the flexible substrate 100a and 100b includes a metal foil, the flexible substrate 100a and 100b may include an insulation layer covering the metal foil in order to insulate the first electrode 110a and 110b from the flexible substrate 100a and 100b.

As such, as the flexible substrate 100a and 100b rolled in the roll 400 is unwound, the solar cell is formed. Therefore, static electricity is apt to be generated on the flexible substrate 100a and 100b by friction either between the roll 400 and the flexible substrate 100a and 100b, or between the flexible substrates 100a and 100b mutually superposed on each other. The flexible substrate may be stained by impurities attached thereto by the static electricity of the flexible substrate 100a and 100b.

When the flexible substrate 100a and 100b having the static electricity is transferred within the process chamber and a PECVD process or a sputtering process is performed, arcing may be generated in the process chamber due to the static electricity of the flexible substrate 100a and 100b. The arcing generated in the process chamber destroys the uniformity of a thin film formed in the process chamber, and even transforms the surface of the flexible substrate 100a and 100b, thereby having a bad influence on the performance of the solar cell.

In order to remove the static electricity and impurities of the flexible substrate 100a and 100b, the embodiment of the present invention may include a step of removing the static electricity and a step of atmospheric pressure plasma cleaning for the flexible substrate 100a and 100b. To this end, as shown in FIGS. 1a and 1b, before the flexible substrate 100a and 100b is transferred into the process chamber for forming the electrode or the semiconductor layer, a static electricity removal process and a cleaning process may be performed by a static electricity remover 200 and an atmospheric pressure plasma cleaner 300

In the embodiment of the present invention, after the step of removing the static electricity is performed, and then the step of atmospheric pressure plasma cleaning may be performed. Otherwise, after the step of atmospheric pressure plasma cleaning is performed, and then the step of removing the static electricity may be performed.

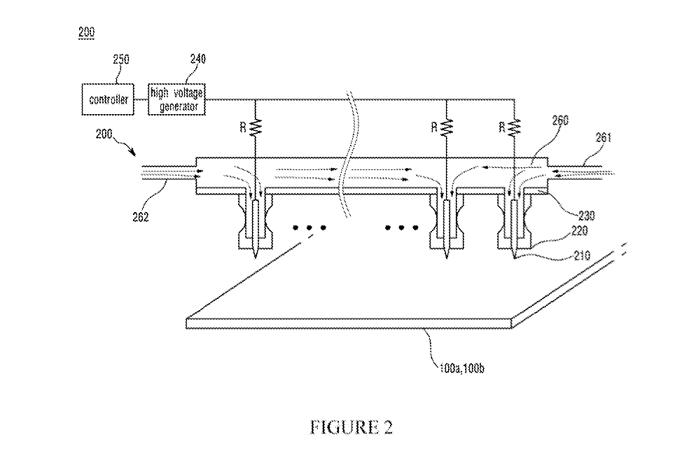

FIG. 2 shows a static electricity remover which can be used to remove the static electricity of the flexible substrate in accordance with the embodiment of the present invention. As shown in FIG. 2, the static electricity remover includes a discharge electrode 210, a discharge electrode socket 220, a ground electrode 230, a high voltage generator 240, a controller 250, an air tank 260 and a protective resistor R.

The discharge electrode 210 functions to generate corona discharge, that is, generates a positive ion and a negative ion. The discharge electrode socket 220 protects the discharge electrode 210 from the external impact and is equipped with an air nozzle (not shown) for injecting the air. The air nozzle functions as a path through which the air is injected at a certain pressure so as to transfer the ion generated by the discharge electrode 210 to the flexible substrate 100a and 100b having the static electricity to be removed. As such, the positive ion and the negative ion neutralize the static electricity of the surface of the flexible substrate 100a and 100b, thereby the static electricity of the surface of the flexible substrate 100a and 100b can be removed.

The air is supplied at a certain pressure to the air nozzle through another air tank 260 and is injected through the air nozzle. In other words, air injectors 261 and 262 are respectively connected to a blower system (not shown) that generates air of a certain pressure, and always inject the air of a certain pressure to the air tank 260. Therefore, the pressure of the air injected from the air nozzle formed in the discharge electrode socket 220 can be also maintained constant.

Meanwhile, the resistor R is connected to the discharge electrode 210. By the resistor R, corona discharge is stably generated, and the electric current capacity can be reduced. Thereby the electric shock from the contact with the discharge electrode 210 can be maximally reduced.

The controller 250 controls the frequency and duty ratio of alternating voltage or controls the supplying and stopping supplying of direct voltage. The ground electrode 230 induces the voltage-applied discharge electrode 210 to generate ion.

As described above, since the static electricity remover of the embodiment of the present invention removes the static electricity at atmosphere, the static electricity can be removed during the transfer of the flexible substrate without loading the flexible substrate in a vacuum chamber. As a result, manufacturing time of the solar cell can be reduced.

Various static electricity removers as well as the static electricity remover shown in FIG. 2 can be used in the embodiment of the present invention.

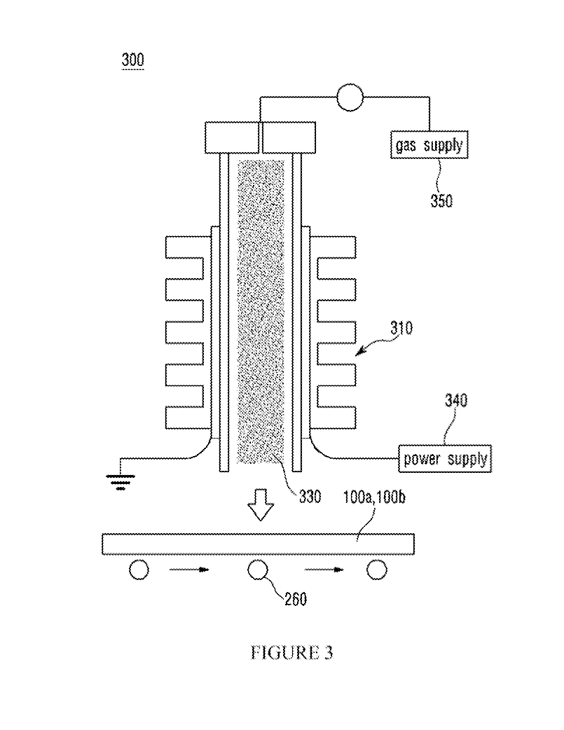

FIG. 3 shows an atmospheric pressure plasma cleaner which can be used to clean a flexible substrate in accordance with the embodiment of the present invention.

As shown in FIG. 3, oxygen radicals 330 generated from plasma reaction is injected to the surface of the flexible substrate 100a and 100b by a plasma generator 310 of the atmospheric pressure plasma cleaner. A power supply 340 applies an alternating voltage to the plasma generator 310. A gas supply apparatus 350 provides gases such as nitrogen, oxygen and air and the like to the plasma generator 310 through a gas pipeline connected to the plasma generator 310. A voltage difference is generated between both electrodes of the plasma generator 310 by the operation of the power supply 340, and then gas plasma is generated by the voltage difference.

Here, a photon, excited atoms and molecules, electrons and ions of the plasma may have energy or may be in an excitation energy state of several or several tens of electron volts. Since the excitation energy is much greater than the binding energy of the impurities on the surface of the flexible substrate 100a and 100b, the surface of the flexible substrate 100a and 100b can be cleaned by means of the plasma.

A transfer device 360 transfers the flexible substrate 100a and 100b at a certain speed during the process of the atmospheric pressure plasma discharge by the plasma generator 310.

Meanwhile, in the atmospheric pressure plasma cleaning process used in the embodiment of the present invention, the surface of the flexible substrate 100a and 100b is cleaned by generating plasma at atmospheric pressure. The atmospheric pressure plasma cleaning can be hereby performed with no use of chemicals at atmospheric pressure instead of vacuum. Therefore, the atmospheric pressure plasma cleaning process can be performed at a lower cost than that of the wet cleaning process using the chemicals.

Further, since the atmospheric pressure plasma cleaning process is performed at atmospheric pressure, the cleaning process can be performed during the transfer of the flexible substrate without loading the flexible substrate in a vacuum chamber. As a result, manufacturing time of the solar cell can be reduced.

As such, in the embodiment of the present invention, it is possible to remove the static electricity and the impurities which are formed during the process of rolling and unrolling the flexible substrate 100a and 100b by the roll 400. Consequently, it is possible to manufacture a stably operating solar cell.

While the embodiment of the present invention has been described with reference to the accompanying drawings, it can be understood by those skilled in the art that the present invention can be embodied in other specific forms without departing from its spirit or essential characteristics. Therefore, the foregoing embodiments and advantages are merely exemplary and are not to be construed as limiting the present invention. The present teaching can be readily applied to other types of apparatuses. The description of the foregoing embodiments is intended to be illustrative, and not to limit the scope of the claims. Many alternatives, modifications, and variations will be apparent to those skilled in the art. In the claims, means-plus-function clauses are intended to cover the structures described herein as performing the recited function and not only structural equivalents but also equivalent structures.

What is claimed is:

1. A method for handling a flexible substrate of solar cell, the method comprising:
providing a flexible substrate;
performing static electricity removal and atmospheric pressure plasma cleaning with respect to the flexible substrate;
forming a first electrode on the flexible substrate;
forming a first conductive semiconductor layer, an intrinsic semiconductor layer and a second conductive semiconductor layer on the first electrode; and
forming a second electrode on the second conductive semiconductor layer.

2. The method of claim 1, wherein the flexible substrate comprises a metal foil or a polymer substrate.

3. The method of claim 1, wherein the first electrode or the second electrode is formed in a process chamber in which a sputtering process is performed.

4. The method of claim 1, wherein the first conductive semiconductor layer, the intrinsic semiconductor layer and the second conductive semiconductor layer are formed in a process chamber in which a PECVD process is performed.

5. The method of claim 1, wherein the static electricity removal and the atmospheric pressure plasma cleaning with respect to the flexible substrate are performed during the transfer of the flexible substrate.

6. The method of claim 1, wherein the static electricity removal is performed at atmosphere.

7. The method of claim 1, wherein, after a laser scribing process is performed on any one of the first electrode and the second electrode, a cleaning process is performed by using an ultra sonic cleaner including a suction head.

8. A solar cell manufacturing system including a flexible substrate, the manufacturing system comprising:
a roll on which the flexible substrate can be wound;
at least one process chamber for forming a first conductive semiconductor layer, an intrinsic semiconductor layer and a second conductive semiconductor layer;
a transfer device passes the flexible substrate through the at least one process chamber as the roll rotates; and
a static electricity remover for removing static electricity of the flexible substrate placed between the roll and the at least one chamber.

9. The solar cell manufacturing system of claim 8, wherein the static electricity remover removes the static electricity at atmosphere.

10. The solar cell manufacturing system of claim 9, wherein the static electricity remover removes the static electricity during the transfer of the flexible substrate.

11. The solar cell manufacturing system of claim 8, further comprising an atmospheric pressure plasma cleaner for cleaning the flexible substrate between the roll and the at least one chamber.

12. The solar cell manufacturing system of claim 11, wherein the atmospheric pressure plasma cleaner cleans the flexible substrate by generating plasma at atmospheric pressure.

13. The solar cell manufacturing system of claim 12, wherein the atmospheric pressure plasma cleaner cleans the flexible substrate during the transfer of the flexible substrate.

14. The solar cell manufacturing system of claim 8, wherein a PECVD process is performed in the at least one process chamber.

15. The solar cell manufacturing system of claim 8, further comprising a first process chamber and a second process chamber for forming a first electrode and a second electrode respectively, wherein the at least one process chamber is placed between the first process chamber and the second process chamber.

16. The solar cell manufacturing system of claim 15, wherein a sputtering process is performed in the first process chamber and the second process chamber.

17. The solar cell manufacturing system of claim 15, further comprising an ultra sonic cleaner for removing conductive particles from the flexible substrate.

18. The solar cell manufacturing system of claim 17, wherein the ultra sonic cleaner comprises a suction head sucking the conductive particles.

19. The solar cell manufacturing system of claim 8, wherein the flexible substrate comprises a metal foil or a polymer substrate.

20. The solar cell manufacturing system of claim 8, wherein, in the at least one process chamber, the number of the process chambers for forming the intrinsic semiconductor layer is greater than the number of the process chambers for forming the first conductive semiconductor layer or the second conductive semiconductor layer.
